(19) United States
(12) Patent Application Publication
(10) Pub. No.: US 2020/0007359 A1
(43) Pub. Date: Jan. 2, 2020

(54) SYSTEM AND METHOD FOR BEACON

(71) Applicant: Molex, LLC, Lisle, IL (US)

(72) Inventors: Christopher BLOUNT, Lisle, IL (US); Giovanni FREZZA, Lisle, IL (US); Michael C. PICINI, Lisle, IL (US); Anthony MACKEY, Lisle, IL (US)

(73) Assignee: Molex, LLC, Lisle, IL (US)

(21) Appl. No.: 16/486,234

(22) PCT Filed: Feb. 15, 2018
(86) PCT No.: PCT/US2018/018349

§ 371 Date: Aug. 15, 2019

Related U.S. Application Data
(60) Provisional application No. 62/459,124, filed on Feb. 15, 2017.

(51) Int. Cl. H04L 12/40; H04L 12/10; H05K 1/14; H04L 12/24

(52) U.S. Cl. CPC H04L 12/40045; H04L 12/10; H05K 1/141; H04L 67/12; H05K 2201/10106; H05K 2201/10151; H05K 2201/10189; H04L 41/0686

(57) ABSTRACT

A beacon includes an interface, a sensor, an indicator and a controller. The controller is communicatively coupled to the interface, the sensor and the indicator, the controller configured to receive control information via the interface and the sensor and to generate control instructions in response to the control information for the indicator.

### RELATED APPLICATIONS

This application claims priority to U.S. Provisional Application 62/459,124, filed Feb. 15, 2017, which is incorporated herein by reference in its entirety.

### TECHNICAL FIELD

This disclosure relates to indicator beacons, and in some examples indicator beacons that connect with a POE network.

### DESCRIPTION OF RELATED ART

This section introduces aspects that may help facilitate a better understanding of the inventions. Accordingly, the statements of this section are to be read in this light and are not to be understood as admissions about what is prior art or what is not prior art.

Devices involved in building automation are traditionally AC powered, so each device requires its own high voltage power line as well as AC/DC power converter. They also require a means of communicating data, either with a second, separate cable or through a wireless connection. When wired, data cables should be kept away from the AC power wires to prevent data loss, complicating the installation. Since wireless sensors have limited range and power, a wireless connection approach may require a distribution of wireless gateways with which to communicate in the building management system. Also, in the current marketplace, different sensor types often require different housings and control circuitry, adding to the cost of each device.

### SUMMARY

In some embodiments, a beacon includes an interface, a sensor, an indicator and a controller. The controller is communicatively coupled to the interface, the sensor and the indicator, the controller configured to receive control information via the interface and the sensor and to generate control instructions in response to the control information for the indicator. Depending on the embodiment, the interface may take the form of a PoE interface, an RS485 interface, and/or some other low-voltage communication interface.

### BRIEF DESCRIPTION OF THE DRAWINGS

The present invention is illustrated by way of example and not limited in the accompanying figures in which like reference numerals indicate similar elements.

FIG. 1 is a block diagram depiction of an array of beacons providing exit information in accordance with various embodiments of the present invention.

FIG. 2 is a block diagram depiction of a beacon in accordance with various embodiments of the present invention.

FIG. 3 is a block diagram depiction of a beacon in accordance with various embodiments of the present invention.

FIG. 4 is a block diagram depiction of various beacon components in accordance with certain embodiments of the present invention.

FIG. 5 is a block diagram depiction of a beacon circuit board assembly in accordance with certain embodiments of the present invention.

FIG. 6 is a block diagram depiction of a controller in accordance with various embodiments of the present invention.

FIG. 7 illustrates a perspective top view of an embodiment of a circuit board assembly.

FIG. 8 illustrates a perspective bottom view of the embodiment depicted in FIG. 7.

FIG. 9 illustrates a perspective top and bottom view of another embodiment of a circuit board assembly.

Specific embodiments of the present invention are disclosed below with reference to various figures and sketches. Both the description and the illustrations have been drafted with the intent to enhance understanding. For example, the dimensions of some of the figure elements may be exaggerated relative to other elements, and well-known elements that are beneficial or even necessary to a commercially successful implementation may not be depicted so that a less obstructed and a more clear presentation of embodiments may be achieved.

Simplicity and clarity in both illustration and description are sought to effectively enable a person of skill in the art to make, use, and best practice the present invention in view of what is already known in the art. One of skill in the art will appreciate that various modifications and changes may be made to the specific embodiments described below without departing from the spirit and scope of the present invention. Thus, the specification and drawings are to be regarded as illustrative and exemplary rather than restrictive or all-encompassing, and all such modifications to the specific embodiments described below are intended to be included within the scope of the present invention.

### DETAILED DESCRIPTION

The detailed description that follows describes exemplary embodiments and is not intended to be limited to the expressly disclosed combination(s). Therefore, unless otherwise noted, features disclosed herein may be combined together to form additional combinations that were not otherwise shown for purposes of brevity.

The disclosure provided herein describes features in terms of preferred and exemplary embodiments thereof. Numerous other embodiments, modifications and variations within the scope and spirit of the appended claims will occur to persons of ordinary skill in the art from a review of this disclosure.

In some embodiments, the beacon 10 is a stand-alone sensor unit with visual indicator that can include, but is not limited, to red, green, blue, white (RGBW) light emitting diode (LED) output, where red can provide one type of indication, green another, blue another, white another, a solid light another, a blinking light another, no light another, etc., to the users. Any other colors are possible, e.g., using combinations of RGBW and/ or other colored LEDs in a mixing chamber, for example, and perhaps also by utilizing a dome or lens to project the light toward users. The sensors and the LED can be mounted on the same circuit board or different circuit boards communicatively connected together. The beacon 10 can be connected with a PoE network and/or low voltage bus, and in some examples is used for building automation to communicate with the tenants of the building to streamline processes. An example controller 118 for connecting power and data signals from a PoE network to the beacon 10 is described below. In some embodiments the controller 118 includes gateway functionality.

In some embodiments, the beacon 10 can be used to aid network diagnostics (related to commissioning path segment restoration (PSR)). For example, green can indicate the system is receiving power, blue can indicate connection with the network, red can indicate a problem with the power, white can indicate no connection to the network, blinking can indicate the light fixture is receiving an update, etc. Other sensors can include, but are not limited to, one or more of ambient light, temperature, occupancy, motion, noise, air quality, humidity, acceleration, proximity, magnetism, pressure, motion, flux, CO/CO2, correlated color temperature (CM, red/green/blue (RGB) light, active or passive infrared (PIR), infrared array, visual information, e.g., from a camera, audio information, e.g., from a microphone, etc., and other desired sensors. The sensors can be used to provide feedback to the beacon 10 so that the beacon 10 can provide a more intelligent notification to users. The beacon 10 can be modular in that different sensors can be added to and/or removed from the beacon 10 over time.

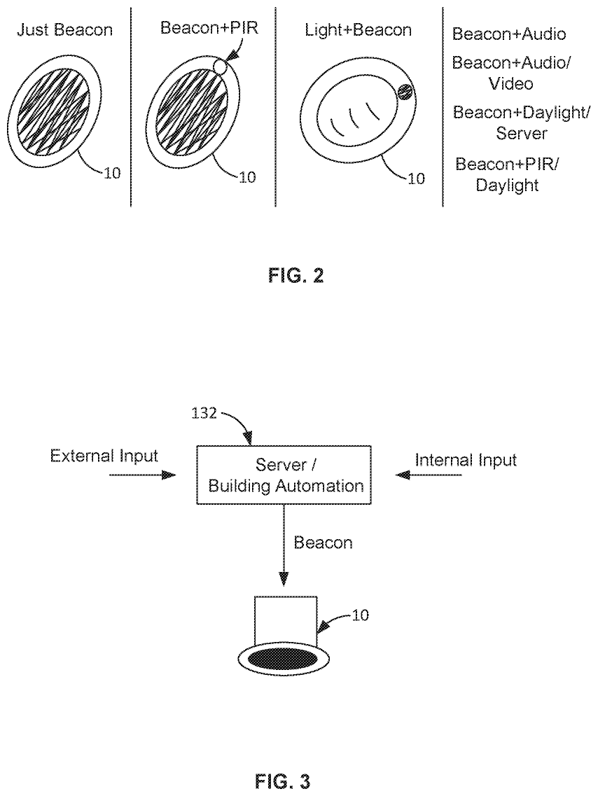

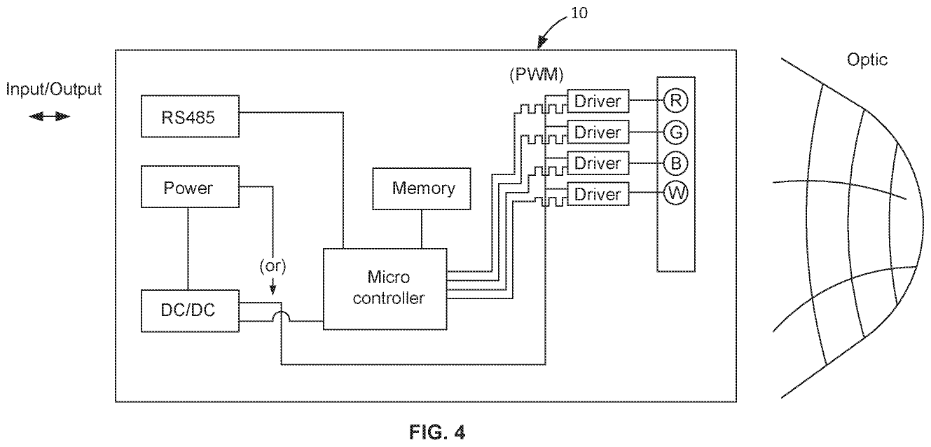

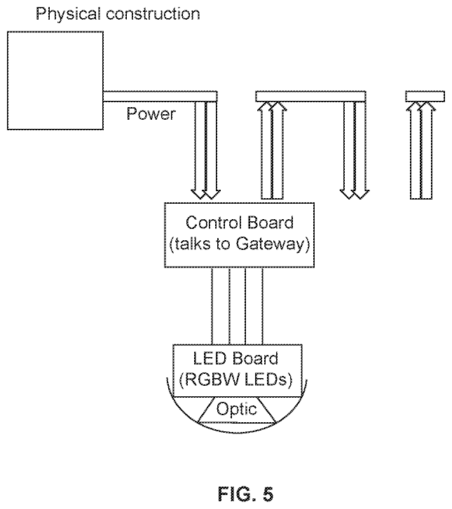

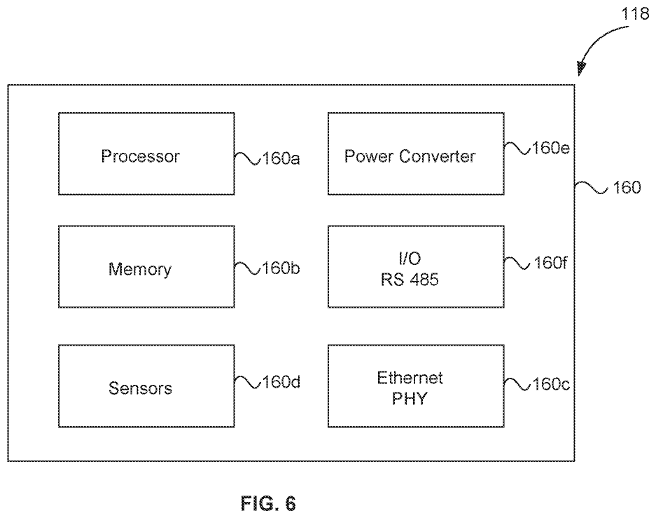

As depicted in FIG. 2, for example, beacon 10 may be a stand-alone visual indicator unit or it may be combined with one or more sensors. As depicted, beacon 10 may have a PIR sensor added, a daylight sensor added, an audio sensor added, and/or a video sensor added. Beacon 10 might also be combined with a light, for example.

In some embodiments, an array or arrays of beacon 10 indicators and potentially sensors, cameras, and audio speakers/microphones) is created to provide visual communication. This can aid in emergency situations, inform on the status of the space or user, assist in-building geographical location, and add diagnostic feedback. In one example, in some implementations, the beacon 10 uses acceleration information from one or more of the sensors to detect an earthquake and activate the light source based on the detection, e.g., illuminating the light source in a way that provides exit information and/or warning information to those near the light source.

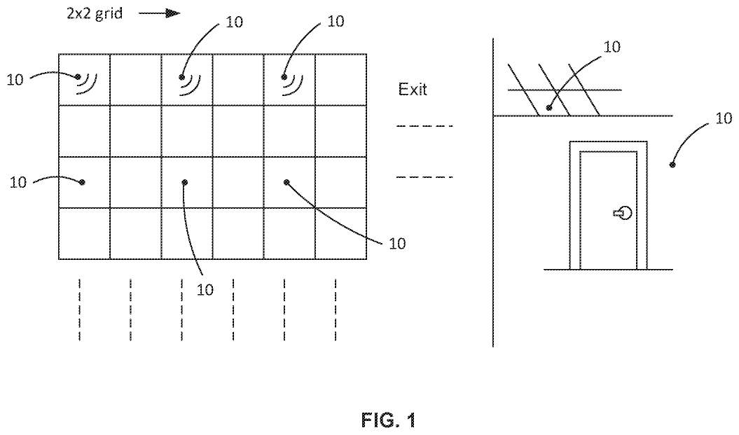

As depicted in FIG. 1, for example, all beacon 10 indicators in the array (the entire floor or building, e.g.) may indicate the type of emergency (fire, earthquake, etc.), while certain beacon 10 indicators may blink in a directional pattern to show the direction of an exit. Beacon 10 indicators may be ceiling mounted or wall mounted and in some cases mounted in recesses. For example, a beacon 10 indicator may be mounted in the ceiling or on the wall outside of a. conference room and indicate an occupancy status or reservation (booking) status for the conference room.

The beacon 10 can include physical connectors for floor mount, surface mount, wall mount, and/or ceiling mount or be embedded in/combined with another device, e.g., a light fixture or actuator device (such as a motor driver, etc.). The beacon 10 can have a PoE connection or a low voltage bus from PoE or other power. The beacon 10 can operate standalone or as part of a greater network infrastructure of controls for building management. In some embodiments, the beacons 10 can be daisy-chain connected together.

Example implementations of the beacon 10 include, but are not limited to, Emergency: fire indication, tornado indication, earthquake indication, flood indication, police/lockdown indication, medical/911 call indication, and/or power outage indication and/or pathway strobes indicating direction of emergency egress, etc.; Status of Space: conference room occupied or unoccupied, booked or unhooked, on call or off call, muted or unmuted, bathroom in use or out of order, health care room status, air quality or temperature/humidity levels, open office, current paging, current maintenance/repair ongoing, school testing or reading, do not disturb, and/or holiday or party lighting, etc.; Status of User: out of office or away at meeting or busy, health care patient status/condition, and/or assistance or call button indication, etc.; Geographic location: open office department indication (finance, legal, human resources (HR)), follow me beacon 10 for pathway to/from front desk, identifying aisles in a warehouse/store for pick location, and/or asset monitoring/locating, etc.; Diagnostic Feedback: lifetime or maintenance indicator, performance feedback, sensor state feedback, network connectivity status, and/or feedback in commissioning of the system or system components, etc.

In some embodiments, a controller 118 may be mounted on, or integrated into, the beacon 10. In some embodiments, the controller 118 may be integrated into a circuit board of the beacon 10. In some embodiments, the controller 118 may be a standalone device and housed separately but still connected to or in communication with the beacon 10. The controller 118 can receive various types of input and provide current and/or control data to the beacon 10, per its configuration, based on the input received. In some embodiments, the controller 118 can receive PoE power and data signals from the Ethernet, and convert the PoE to a non-PoE protocol for outputting via a connector. As can be appreciated, such a. construction allows the connector to have relatively few inputs (one pair of power inputs and one pair of signal inputs, e.g., voltage, ground, RS+ and RS− for the RS485 protocol—and if desired the signal inputs could be multiplexed onto the power inputs) while providing a variety of control outputs.

As can be appreciated, the connectors typically provide at least two power terminals. The power can be provided from an Ethernet cable providing power over Ethernet (PoE) or other desirable input. An advantage of using a PoE source is that the power source is low voltage, which simplifies the design of the beacon 10 and also makes it simple to provide power (one simply runs a network cable to the location and power is provided).

If PoE is used to power the beacon 10 then an RJ45 port (or other suitable port) can be provided in the beacon 10 along with an appropriate driver.

The controller 118 can connect with a PoE network via the RJ45 port to receive power and control signals from the Ethernet, and output power and control signals to components of the beacon 10, e.g., LEDs, speakers and/or other components of the beacon 10. The controller 118 may also receive signals from the sensors of beacon 10 and process the sensor signals to directly control the beacon 10 based on the sensor signals, and/or send the sensor signals to a server connected with the Ethernet for processing and sending new control signals to the controller 118. In some embodiments, the controller 118 can convert the Ethernet or other high-level protocol into a lower level protocol, e.g., convert PoE to RS232, RS485, CAN, BACnet, digital addressable lighting interface (DALI), TRANSCEND by MOLEX, etc., and vice versa, for controlling the beacon 10. The controller 118 can make wired and/or wireless connections with the beacon 10, e.g., via a wiring harness and/or Bluetooth low energy (BTLE), ZigBee, EnOcean, IEEE 802.11 (WiFi), etc.

To control the beacons 10, convert from one protocol to another, send power and/or control signaling to the beacons 10, and/or perform other logic for the beacons 10, the controller 118 can include circuit board assembly 160 for accommodating electrical components of the controller 118. The electrical components may, for example, include one or more processors 160a and one or more memory devices 160b, e.g., in some embodiments implemented as a microprocessor with memory. The memory devices can include one or more of a program memory, a cache, random access memory (RAM), a read only memory (ROM), a flash memory, a hard drive, etc., and/or other types of memory. The memory boob can store instructions (e.g., compiled executable program instructions, un-compiled program code, some combination thereof, or the like)), which when performed (e.g., executed, translated, interpreted, and/or the like) by the processor 160a, causes the processor 160a to perform the translations, logic and other processes described herein. For example, the processor 160a can translate Ethernet based protocol signals, received via Ethernet PHY 160c, into non-Ethernet based protocol signals, and vice versa, e.g., for providing communication between a server 132 and an LED board. (Server 132 can receive internal (such as from beacon 10 or other devices) and/or external inputs, and in response, actuate beacon 10. Of course, beacon 10 may detect sensor inputs and actuate itself.)

The circuit board assembly 160 can also include sensor 160d. More than one sensor type and/or multiple sensors 160d can be included on the circuit board assembly 160. The circuit board assembly 160 can also include a power converter 160e, e.g. for converting 48 VDC power from the PoE input to 5 VCD and 3.3 VDC, etc. to power processor 160a, the Ethernet PHY 160c, etc. The controller 118 can also pass the power to other devices, e.g., via RS485 input/output (I/O) 160f, LED drivers, etc. Additional or alternative components may be included on the circuit board assembly 160, including, but not limited to, an onboard analog-to-digital converter and/or other circuitry that may be configured to convert analog signals into digital signals, e.g., for processing. The circuit board assembly 160 can also include digital conditioning circuitry for processing the signals, etc.

In some embodiments, the circuit board assembly 160 is sized and shaped to fit the beacon 10, e.g., via round shapes, oval shapes, rectangular shapes, square shapes, triangular shapes, irregular shapes, etc. The circuit board assembly 160 may include one board or more than one board connected with each other and in some embodiments stacked on each other. It will be appreciated that where circuit board assembly 160 is described, it is described by way of non-limiting example, such that alternative assemblies on which circuitry and/or other electronic components may be embodied may be substituted for circuit board assembly 160 within the scope of the disclosure, including but not limited to, circuit boards having point to point construction, application-specific integrated circuit (ASIC), field programmable gate array (FPGA), etc. In some embodiments, control circuitry is located on the circuit board assembly 160.

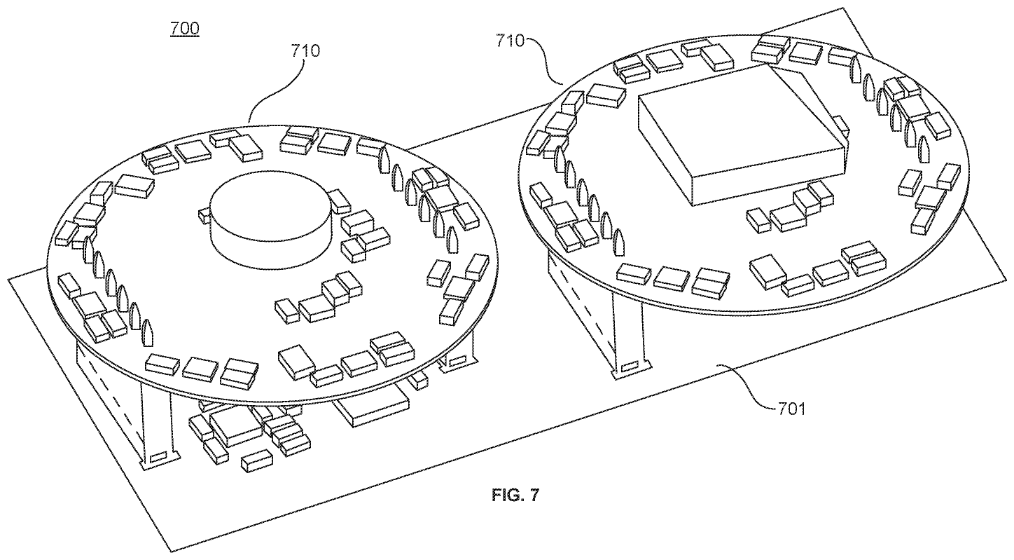

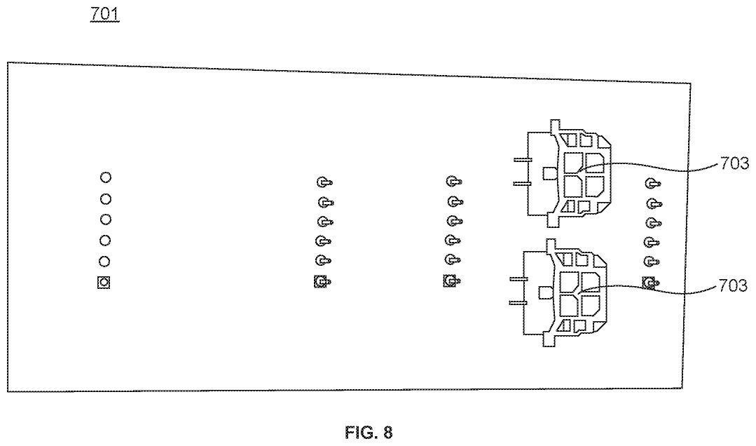

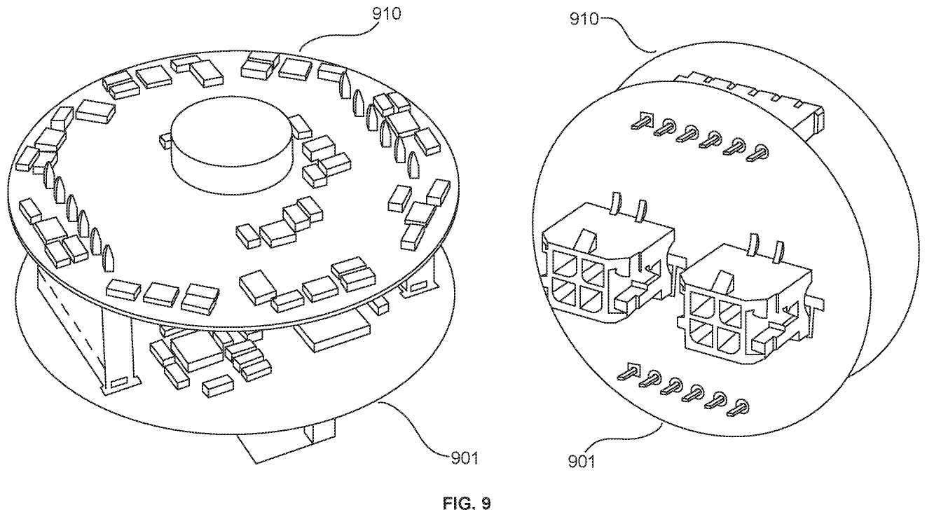

FIGS. 7-9 illustrate example circuit board assembly embodiments. Circuit board assembly 700 includes a base board 701 with daughter boards 710 attached on top and connectors 703 attached below. In this embodiment, base board 701 serves as a control board while daughter boards 710 are sensor boards. For example, base board 701 handles power conversion and signaling to and from the daughter board components and signaling to and from a PoE gateway. In another embodiment, base board 901 supports a single daughter board 910. Each of the daughter boards can be different from one another, can include a sensor (one or more can include a stand-alone beacon (one or more), and/or can include some beacon-sensor combination. Additional or alternative components may be included on daughter boards as well. Also, in other embodiments, base boards may communicate with a building automation controller/server rather than a PoE gateway.

Connectors such as connectors 703 provide a wired connection between a circuit board assembly and a building automation controller/server or a PoE gateway. In the case of a TRANSCEND bus implementation, low voltage power along with data is provided in a single connection. There is no need to wire or connect high voltage AC power, and there is no complicating second data-only wire. Dual connectors can enable daisy-chaining where both data and power are passed from a server or gateway to one circuit board assembly then on to the next and on to the next until the chain ends. In this manner, a chain or series of sensors/beacons tens of meters long can be set up in a building. Barriers that would stop wireless signals can be routed around with such lengths of wired connections available.

These circuit board assembly embodiments described above strive to achieve a modular design with a common base board and housing but different daughter boards and faceplates. Cost can be reduced for each beacon/sensor type if only the daughter board and module faceplate need to be changed from one type to the next.

Each daughter board type can have an identifying resistor so that the base board knows which type is connected (for example, by using voltage and current to measure and determine which resistor and therefore which daughter board is connected). This can simplify board firmware, enabling one version for all base board—daughter board combinations. Also, daughter boards can be swapped out and changed without needing to reprogram components on the base board.

A person of skill in the art would readily recognize that steps of various described methods can be performed by programmed computers. Herein, some embodiments are intended to cover program storage devices, e.g., digital data storage media, which are machine or computer readable and encode machine-executable or computer-executable programs of instructions where said instructions perform some or all of the steps of methods described herein. The program storage devices may be, e.g., digital memories, magnetic storage media such as a magnetic disks or tapes, hard drives, or optically readable digital data storage media. The embodiments are also intended to cover computers programmed to perform said steps of methods described herein.

Benefits, other advantages, and solutions to problems have been described herein with regard to specific embodiments of the present invention. However, the benefits, advantages, solutions to problems, and any element(s) that may cause or result in such benefits, advantages, or solutions, or cause such benefits, advantages, or solutions to become more pronounced are not to be construed as a critical, required, or essential feature or element of any or all the claims.

As used herein and in the appended claims, the term “comprises,” “comprising,” or any other variation thereof is intended to refer to a non-exclusive inclusion, such that a process, method, article of manufacture, or apparatus that comprises a list of elements does not include only those elements in the list, but may include other elements not expressly listed or inherent to such process, method, article of manufacture, or apparatus. The terms a or an, as used herein, are defined as one or more than one. The term plurality, as used herein, is defined as two or more than two. The term another, as used herein, is defined as at least a second or more. Unless otherwise indicated herein, the use of relational terms, if any, such as first and second, top and bottom, and the like are used solely to distinguish one entity or action from another entity or action without necessarily requiring or implying any actual such relationship or order between such entities or actions.

The terms including and/or having, as used herein, are defined as comprising (i.e., open language). The term coupled, as used herein, is defined as connected, although not necessarily directly, and not necessarily mechanically. Terminology derived from the word “indicating” (e.g., “indicates” and “indication”) is intended to encompass all the various techniques available for communicating or referencing the object/information being indicated. Some, but not all, examples of techniques available for communicating or referencing the object/information being indicated include the conveyance of the object/information being indicated, the conveyance of an identifier of the object/information being indicated, the conveyance of information used to generate the object/information being indicated, the conveyance of some part or portion of the object/information being indicated, the conveyance of some derivation of the object/information being indicated, and the conveyance of some symbol representing the object/information being indicated.

The detailed and, at times, very specific description herein is provided to effectively enable a person of skill in the art to make, use, and best practice the present invention in view of what is already known in the art. In the examples, specifics are provided for the purpose of illustrating possible embodiments of the present invention and should not be interpreted as restricting or limiting the scope of the broader inventive concepts.

What is claimed is:

1-25. (canceled)

26. A circuit board assembly comprising:
an Ethernet port;
a power converter coupled to the Ethernet port;
a processing unit comprising a processor and a memory device, the processing unit coupled to the power converter and communicatively coupled to the Ethernet port; and
a sensor coupled to the power converter and communicatively coupled to the processing unit, the power converter being configured to convert power received via the Ethernet port for use by the processing unit and the sensor, the processing unit being configured to receive sensor signaling from the sensor and send sensor information via the Ethernet port in response to the sensor signaling.

27. The circuit board assembly of claim 26, wherein the sensor comprises at least one of an ambient light sensor, a temperature sensor, an occupancy sensor, a motion sensor, a noise sensor, an air quality sensor, a humidity sensor, an acceleration sensor, a proximity sensor, a magnetism sensor, a pressure sensor, a motion sensor, a flux sensor, a CO/CO2 sensor, a correlated color temperature (CCT) sensor, a red/green/blue (RGB) light sensor, an active or passive infrared (PIR) sensor, a visual information sensor and an audio information sensor.

28. The circuit board assembly of claim 26, wherein the processing unit further comprises an Ethernet PHY.

29. The circuit board assembly of claim 26, the processing unit being further configured to receive sensor signaling from the sensor and to determine whether any indication of the sensor signaling should be generated as sensor information and sent via the Ethernet port.

30. The circuit board assembly of claim 26, further comprising a plurality of circuit boards.

31. The circuit board assembly of claim 30, wherein the plurality of circuit boards includes a first circuit board and a second circuit board, wherein the Ethernet port is on the first circuit board and the sensor is on the second circuit board.

32. The circuit board assembly of claim 31, the processing unit being further configured to determine the type of sensor on the second circuit board.

33. The circuit board assembly of claim 26, wherein the Ethernet port is one of a plurality of Ethernet ports configured for daisy-chaining to another circuit board assembly.

34. The circuit board assembly of claim 26, wherein the sensor further comprises a connector configured for daisy-chaining to another sensor.

35. A circuit board assembly comprising:
an Ethernet port;
a power converter coupled to the Ethernet port;
a processing unit comprising a processor and a memory device, the processing unit coupled to the power converter and communicatively coupled to the Ethernet port;
a sensor interface coupled to the power converter; and
a sensor communicatively coupled to the processing unit, the power converter being configured to convert power received via the Ethernet port for use by the processing unit and the sensor interface, the processing unit being configured to receive sensor signaling via the sensor interface and send sensor information via the Ethernet port in response to the sensor signaling.

36. The circuit board assembly of claim 35, wherein the sensor interface comprises an input/output (I/O) driver and a connector configured to support a wired connection to the sensor.

37. The circuit board assembly of claim 36, the I/O driver being configured to support communication via at least one of RS232 protocol, RS485 protocol, CAN protocol, BACnet protocol, digital addressable lighting interface (DALI) protocol, and TRANSCEND protocol by MOLEX.

38. The circuit board assembly of claim 35, wherein the sensor interface comprises a wireless transceiver configured to support a wireless connection to the sensor.

39. The circuit board assembly of claim 38, the wireless transceiver being configured to support communication via at least one of Bluetooth low energy (BTLE), ZigBee, EnOcean, and IEEE 802.11 (WiFi).

40. The circuit board assembly of claim 35, the processing unit being further configured to determine the type of sensor communicatively coupled to the processing unit via the sensor interface.

41. The circuit board assembly of claim 35, wherein the Ethernet port is one of a plurality of Ethernet ports configured for daisy-chaining to another circuit board assembly.

42. The circuit board assembly of claim 35, wherein the sensor further comprises a connector configured for daisy-chaining to another sensor.
